(19) United States
(12) Patent Application Publication
(10) Pub. No.: US 2016/0160351 A1
(43) Pub. Date: Jun. 9, 2016

(54) LINER ASSEMBLY AND SUBSTRATE PROCESSING APPARATUS HAVING THE SAME

(71) Applicant: CHARM ENGINEERING CO., LTD., Yongin-Si (KR)

(72) Inventors: Young-Soo SEO, Osan-Si (KR); Young-Ki HAN, Seoul (KR); Jun-Hyeok LEE, Osan-Si (KR); Woo-Sik SHIN, Bucheon-Si (KR); Noh-Sun MYOUNG, Cheonan-Si (KR)

(21) Appl. No.: 15/042,136

(22) Filed: Feb. 11, 2016

Related U.S. Application Data
(62) Division of application No. 13/915,573, filed on Jun. 11, 2013, now abandoned.

(30) Foreign Application Priority Data
Mar. 22, 2013 (KR) 10-2013-0030917

(51) Int. Cl. C23C 16/513

(52) U.S. Cl. CPC C23C 16/513

(57) ABSTRACT

Provided are a liner assembly and a substrate processing apparatus including the liner assembly. The liner assembly includes a side liner, an intermediate liner, and a lower liner. The side liner has a cylindrical shape with upper and lower portions opened. The intermediate liner is disposed under the side liner and has a plurality of first holes passing therethrough in a vertical direction. The lower liner is disposed under the intermediate liner. Here, the plurality of first holes are formed in different sizes and numbers in a plurality of regions.

### CROSS-REFERENCE TO RELATED APPLICATION

This application is a divisional of U.S. patent application Ser. No. 13/915,573, filed Jun. 11, 2013, which claims priority to Korean Patent Application No. 10-2013-0030917 filed on Mar. 22, 2013 and all the benefits accruing therefrom under 35 U.S.C. §119, the contents of which are incorporated by reference in their entirety.

### BACKGROUND

The present disclosure relates to a substrate processing apparatus, and more particularly, to a liner assembly and a substrate processing apparatus including the same, which can improve the process uniformity.

Generally, a semiconductor process is performed to manufacture semiconductor devices, display devices, light emitting diodes or thin film solar cells. That is, a certain stacked structure is formed by repeatedly performing a thin film deposition process of depositing thin films of specific materials on substrates, a photo process of exposing selected areas of these thin films using photosensitive materials, and an etching process of performing patterning by removing thin films from the selected areas.

A Chemical Vapor Phase Deposition (CVD) method may be used for the thin film deposition process. In the CVD method, the raw material gases supplied into a reaction chamber cause a chemical reaction on an upper surface of a substrate to grow up thin films. Also, the technology of miniaturizing and highly integrating the patterns is being studied and developed as semiconductor devices tends to be miniaturized. For this, a Plasma Enhanced CVD (PECVD) method for activating raw material gases to form plasma can be used.

General PECVD apparatuses include a chamber having a certain space therein, a showerhead disposed at an upper inner side of the chamber, a substrate support disposed at a lower inner side of the chamber and supporting a substrate, and a plasma generation source such as an electrode or an antenna disposed inside or outside the chamber. Here, the plasma generation source can be divided into the Capacitive Coupled Plasma (CCP) type using an electrode, and the inductive coupled plasma type using an antenna.

The most important thing to deposit thin films using such a PEVCD apparatus can be regarded as a stable and uniform plasma generation source and a uniform gas flow inside the chamber. However, the plasma generated in the capacitive coupled plasma apparatus has an advantage that ion energy is high due to an electric field, but there is a limitation in that a substrate and a thin film formed on the substrate are damaged by ions with high energy, and the damage degree by ions with high energy is significant as patterns are getting minute. Also, the inductive coupled plasma apparatus has a limitation in that while the ion density of plasma formed within the chamber is uniform in the central region of the chamber, the uniformity of the ion density is lowered as getting closer to the edge region. Such a difference between the ion densities appears more remarkable as substrates and chambers become larger in size.

Also, the gas flow inside the reaction chamber becomes non-uniform due to an unbalance of a pumping path for discharging the inside of the chamber, and thus there occur many limitations on process such as reduction of deposition uniformity of thin films and generation of particles. For example, since a shaft is prepared on a central portion of the lower side of the chamber, a discharge port has to be formed outside the lower part of the chamber, and thus a region on which the discharge port is formed and other regions differ from each other in discharge time. Accordingly, a duration when gases on a substrate are staying becomes different, lowering the deposition uniformity of thin films. Particularly, when a low pressure process of about 20 mTorr or less is used, raw materials introduced into the reaction chamber are reduced, making it difficult to improve the deposition uniformity using gases.

In order to solve this limitation, many methods are being attempted, and the most representative methods are a method of mounting a manifold and a method of forming at least one discharge port on a side surface of the chamber. However, since a shaft is prepared on a central portion of the lower portion of the chamber, a discharge apparatus is mounted on the side surface of the chamber. Also, in even case of mounting a turbo pump to perform a low pressure process, since the shaft is prepared on a central portion of the lower side of the chamber, the turbo pump has to be prepared on the side surface of the chamber. When the discharge apparatus is prepared on the side surface of the chamber, there is a limitation in uniformly maintaining the internal pressure of the chamber uniform. Also, when several components are inserted into the chamber, the uniformity of the plasma may be affected.

Meanwhile, Korean Publication Patent No. 1997-0003557 discloses a capacitive coupled plasma apparatus including a upper reactor electrode, and a lower reactor electrode located on a lower side of the upper reactor electrode, and Korean Patent No. 10-0963519 discloses an inductive coupled plasma apparatus including a gas spray part located on a upper portion of a chamber and introducing a source gas into the chamber, an antenna supplied with a source power, and an electrostatic chuck fixing a substrate and supplied with a bias power.

### SUMMARY

The present disclosure provides a substrate processing apparatus, which can prevent a damage of a substrate or a thin film deposited on the substrate.

The present disclosure also provides a substrate processing apparatus, which can improve the uniformity of a thin film deposited on a substrate.

In accordance with an exemplary embodiment, a liner assembly include: a side liner having a cylindrical shape with upper and lower portions opened; an intermediate liner disposed under the side liner and having a plurality of first holes passing therethrough in a vertical direction; and a lower liner disposed under the intermediate liner, wherein the plurality of first holes are formed in different sizes and numbers in a plurality of regions.

The liner assembly may include an upper liner over the side liner.

The lower liner and the intermediate liner may have an opening of a smaller size than a diameter of the side liner at a central portion thereof, respectively.

The liner assembly may include a protrusion upwardly protruding from an inner side of the lower liner and contacting the intermediate liner. Here, the protrusion may have a plurality of second holes formed therein.

The first holes may increase in size or number when going from one region to the other region opposite thereto.

In accordance with another exemplary embodiment, a substrate processing apparatus includes: a chamber provided with a reaction space and a discharge port at a lower side surface thereof; a substrate support disposed in a chamber to support a substrate; a gas supply assembly for supplying a process gas into the chamber; a plasma generation unit for generating a plasma of the process gas; and a liner assembly disposed in the chamber, wherein the liner assembly includes a side liner having a cylindrical shape with upper and lower portions opened, an intermediate liner disposed under the side liner and having a plurality of first holes passing therethrough in a vertical direction and a lower liner disposed under the intermediate liner, and the plurality of first holes are formed in different sizes and numbers in a plurality of regions.

The gas supply assembly may include: a first shower head; a second shower head including a first body disposed under the first shower head while being spaced from the first shower head and a second body having a plurality of first spray holes and second spray holes; a connection tube extending in a vertical direction to connect between the first body and the second spray hole.

The plasma generation unit may include a power supply unit that applies power to at least one of the first shower head, the first body, and the second body.

The power supply unit may form a region for generating a first plasma between the first shower head and the second body and a region for generating a second plasma between the first body and the second body, and may apply power such that one of the first and second plasmas has a higher ion energy and density and the other thereof has a lower ion energy and density.

The gas spray assembly may include a shower head that is supplied with power for generating a plasma to form a first plasma region at an inner side or an outer side thereof.

The substrate processing apparatus may further include: a plasma generation tube extending inside the chamber in a longitudinal direction of the chamber and penetrating the shower head; and an antenna disposed to surround an outer circumferential surface of the plasma generation tube and supplied with power for generating a plasma.

The shower head may include a first shower head supplied with power and a second shower head disposed under the first shower head while being spaced from the first shower head and grounded, and the first plasma region may be a region between the first shower head and the second shower head.

The substrate processing apparatus may further include: a discharge unit connected to the discharge port and disposed on an outer side portion of the chamber to discharge an inside of the chamber; and a filter unit disposed between the plasma generation unit and the substrate support unit to block a portion of the plasma of the process gas.

The lower liner and the intermediate liner may have an opening having a smaller diameter than a diameter of the side liner at a central portion and receiving a shaft for supporting the substrate support, respectively.

The substrate processing apparatus may further include a protrusion upwardly protruding from an inner side of the lower liner and contacting the intermediate liner, wherein the protrusion has a plurality of second holes formed therein.

### BRIEF DESCRIPTION OF THE DRAWINGS

Exemplary embodiments can be understood in more detail from the following description taken in conjunction with the accompanying drawings, in which:

FIGS. 1 to 3 are cross-section views illustrating a substrate processing apparatus in accordance with first to third embodiments;

FIGS. 4 to 6 are cross-sectional views illustrating a substrate processing apparatus in accordance with fourth to sixth embodiments;

FIG. 7 is a cross-sectional view illustrating a substrate processing apparatus in accordance with a seventh embodiment;

FIGS. 8 to 10 are schematic views illustrating a liner assembly in accordance with an embodiment;

FIG. 11 is a view illustrating a thin film deposition of a substrate processing apparatus

FIGS. 12 and 13 are cross-sectional views illustrating a substrate processing apparatus in accordance with eighth and ninth embodiments.

### DETAILED DESCRIPTION OF EMBODIMENTS

Hereinafter, specific embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

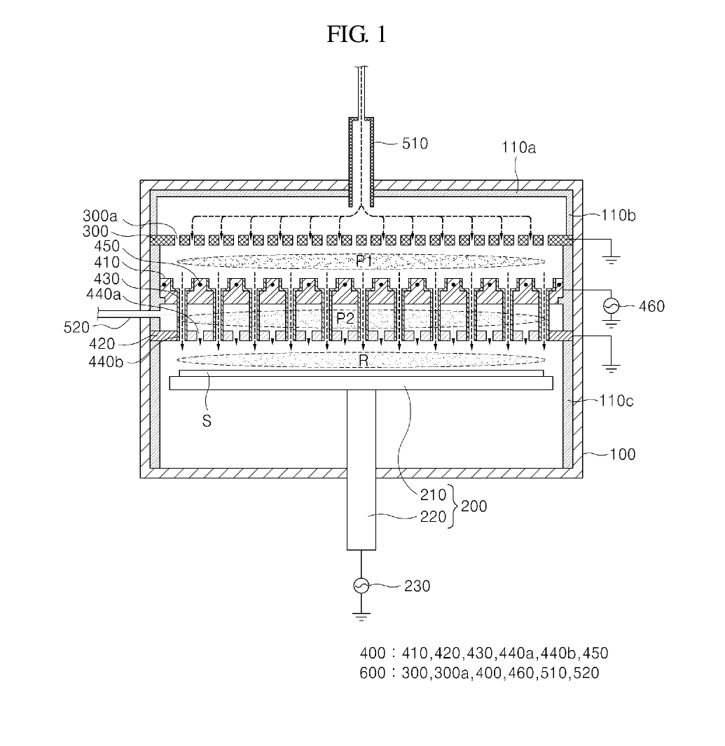

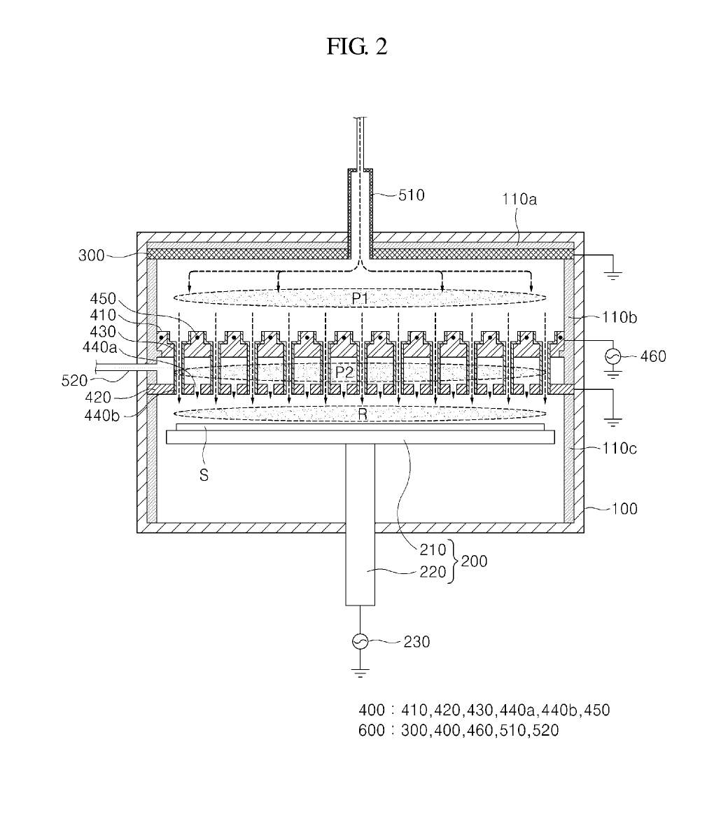

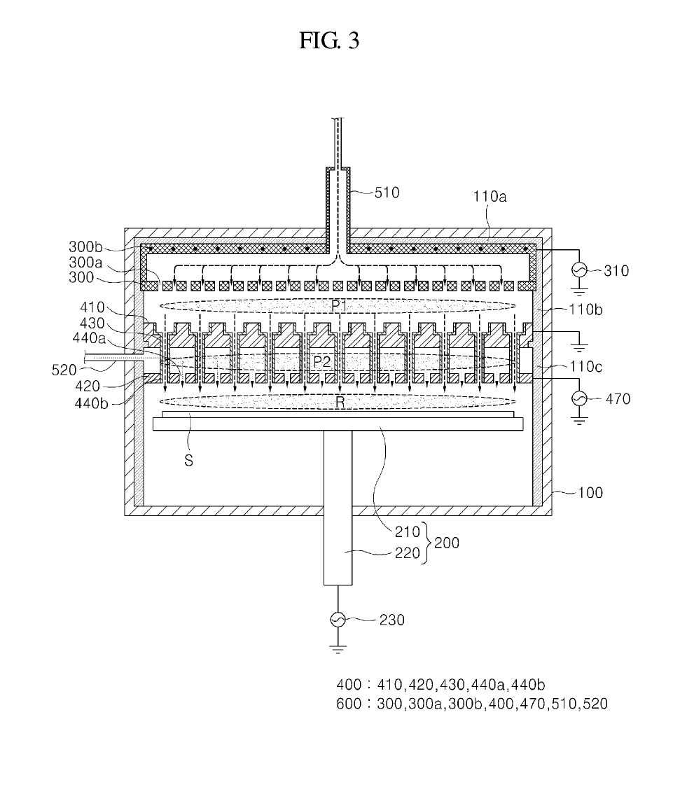

FIG. 1 is a cross-sectional view illustrating a substrate processing apparatus in accordance with a first embodiment, and FIGS. 2 and 3 are cross-sectional views illustrating substrate processing apparatuses in accordance with second and third embodiments.

Referring to FIG. 1, the substrate processing apparatus in accordance with the first embodiment may include a chamber 100 having an internal space for processing a substrate S, a substrate supporting unit 200 disposed inside the chamber 100 to fixedly support the substrate S thereon, and a gas spray assembly 600 disposed over the substrate supporting unit 200 inside the chamber 100 to spray a raw material gas. Here, the gas spray assembly 600 may include a first shower head 300 disposed over the substrate supporting unit 200 inside the chamber 100, a second shower head 400 including first and second bodies 410 and 420 spaced from each other in a vertical direction under the first shower head 300 and spraying a raw material gas, a first gas supply line 510 supplying a raw material gas to the inside or lower side of the first shower head 300, a second gas supply line 520 supplying a raw material gas into a gap between the first body 410 and the second body 420, and a first power supply unit 460 applying power to the second body 420. Also, the raw material gases supplied through the first and second gas supply lines 510 and 520 may be the same or different from each other. Also, the raw material gas may be a deposition gas for depositing a thin film on the substrate S, or may be an etching gas for etching the substrate S or the thin film.

FIGS. 1 to 3 are cross-section views illustrating a substrate processing apparatus in accordance with first to third embodiments

The chamber 100 may be manufactured in a hollow hexahedral shape, and may have a certain internal space therein. The shape of the chamber 100 may not be limited to the hexahedral shape, but may be manufactured into various shapes corresponding to the shape of the substrate S. Although not shown, a loading hole (not shown) for loading and unloading the substrate S may be prepared at one side of the chamber 100, and a pressure control unit (not shown) for controlling the internal pressure of the chamber 100 and a discharge unit (not shown) for discharging the inside of the chamber 100 may also be provided. This chamber 100 may be grounded. In the substrate processing apparatus in accordance with this embodiment, since the chamber 100 is grounded, power, e.g., RF power is applied to the second shower head 400, and the first shower head 300 is grounded, the chamber 100, the second shower head 400, and the first shower head 300 may be insulated among one another. Thus, a first insulating member 110a may be mounted on an upper wall over the first shower head 300, and a second insulating member 110b may be mounted on the inner side wall of the chamber 100 so as to surround over the first shower head 300. Also, a third insulating member 110c may be mounted on the inner side wall between the first shower head 300 and the first body 410 and under the second body 420. Here, the first to third insulating members 110a to 110c may be manufactured using a plate including an insulating material, e.g., ceramic or Pyrex, or may be manufactured in a form of coating film by coating a material including ceramic or Pyrex.

The substrate supporting unit 200 may be disposed under the second shower head 400 in the chamber 100, and may include a substrate support 210 on which the substrate S is seated and a shaft 220 having one end thereof connected to the substrate support 210 and the other end thereof protruding from the lower part of the chamber 100 to be connected to the second power supply unit 230. The substrate support 210 may be a unit that can fixedly support the substrate S using a vacuum adsorption force or an electrostatic chuck that fixedly supports the substrate S using an electrostatic force. However, without being limited thereto, various kinds of unit that can support the substrate S can be used as the substrate support 210. Also, although not shown, a heater (not shown) for heating the substrate S and a cooling line (not shown) for cooling the substrate 210 or the substrate S may be mounted in the substrate support 210. Although not shown, the other end of the shaft 220 may be connected to a driving unit (not shown) that vertically moves or rotates the shaft 220 or the substrate support 210.

The first shower head 300 may be disposed under the first insulating member 110a mounted onto the upper wall in the chamber 100. The first shower head 300 in accordance with the embodiment may be manufactured in a plate shape, and may include a plurality of holes communicating in a vertical direction. The upper part of the first shower head 300 may be connected to the first gas supply line 510 that supplies a raw material gas. Thus, the raw material gas supplied from the first gas supply line 510 may be diffused into a region between the first insulating member 110a and the first shower head 300, and then may be sprayed to a lower side through the plurality of holes 300a prepared in the first shower head 300. The first shower head 300 may be grounded. For this, at least one end of the first shower head 300 may contact the inner wall of the chamber 100 that is grounded, or may be separately grounded regardless of the chamber 100.

The second shower head 400 may include a first body 410 disposed under the first shower head 300 while being spaced from the first shower head 300, a second body 420 disposed under the first body 410 and having a plurality of first spray holes 440a and a plurality of second spray holes 440b spraying a raw material gas, a plurality of connection tubes 430 penetrating the first body 410 and the second body 420 and spraying the raw material gas, and a cooling unit 450 disposed in the first body to cool the first body 410. Here, a region where the plurality of connection tubes 430 are not disposed between the first body and the second body 420 may be an empty space, and the empty space between the first body 410 and the second body 420 may communicate with the plurality of first spray holes 440a prepared in the second body 420. Also, the second gas supply line 520 may have at least one end thereof inserted into the chamber 100 while penetrating the side wall of the chamber 100, supplying a raw material gas between the first body 410 and the second body 420 of the second shower head 400. However, without being limited thereto, the second gas supply line 520 may extend from the upper side to the lower side of the chamber 100, allowing one end thereof to be located at a space between the first body 410 and the second body 420 of the second shower head 400.

The first body 410 may be disposed under the first shower head 300 while being spaced from the first shower head 300, and may be connected to the first power supply unit 460 that applies power, e.g., RF power for generating plasma. For this, at least one end of the first power supply unit 460 may penetrate the chamber 100 and the third insulating member 110c to be connected to the first body 440. Also, when power is supplied to the first body 410, unnecessary heat may be generated in the first body 410. Accordingly, a cooling unit 450 may be inserted into the first body 410. The cooling unit 450 may include a pipe in which a cooling medium, e.g., water or nitrogen gas flows.

The second body 420 may be disposed under the first body 410 while being spaced from the first body 410, and at least one end of the second body 420 may contact the inner side wall of the chamber 100 that is grounded or may be separately grounded regardless of the chamber 100. A plurality of first spray holes 440a and a plurality of second spray holes 440b may be prepared in the second body 420. The first spray hole 440a and the second spray hole 440b may have upper and lower parts opened, respectively, and may be disposed spaced from each other on the second body 420. That is, the plurality of first spray holes 440a may be located, or the first spray hole 440a may be located between the plurality of second spray holes 440b. In order words, the first spray hole 440a and the second spray hole 440b may be alternately disposed on the second body 420. Here, the plurality of first spray holes 440a may be a flow passage through which plasma generated between the first body 410 and the second body 420 is sprayed to the lower side of the second body 420. Also, the plurality of second spray holes 440a may be a space into which the connection tube 430 described later is inserted.

The connection tube 430 may be manufactured in a pipe shape having upper and lower part opened and having an internal space, and may be inserted into the first body 410 and the second body 420 so as to penetrate the first and second bodies 410 and 420 in a vertical direction. That is, the connection tube 430 may penetrate the first body 410, and may have one end thereof inserted into the second spray hole 440b prepared in the second body 420. Thus, the connection tube 430 may become located between the plurality of first spray holes 440b on the second body 420. The connection tube 430 may be a flow passage through which plasma generated between the first shower head 300 and the first body 410 moves to the lower side of the second body 420. Also, a region of the connection tube 430 that is located at the first body 410 may be formed to have a diameter smaller than the diameters of regions that are under the first body 410 and inserted into the second spray hole 440b of the second body 420. preferably, the diameters of the regions of the connection tube 430 that are under the first body 410 and inserted into the second spray hole 440b of the second body 420 may be equal to each other, the diameters of the regions that are under the first body 410 and inserted into the second spray hole 440b may be formed to be smaller than the diameter of the region located in the first body 410. For example, the connection tube 430 may be manufactured to have a cross-section of a T-shape. However, without being limited thereto, the connection tube 430 may be manufactured to have various shapes that connect between the first body 410 and the second body 420 and have an internal space in which a raw material gas flows. Also, the connection tube 430 may be manufactured using a plate including an insulating material, e.g., ceramic or Pyrex, or may be manufactured in a form of coating film by coating a material including ceramic or Pyrex so as to insulate between the first body 410 and the second body 420. The inner diameter of the connection tube 430 and the size of the first spray hole 440a prepared in the second body 420 may be equal to or greater than about 0.01 inch. This is for preventing the generation of arcking upon application of power to the second shower head 400 and suppressing the generation of parasitic plasma.

Hereinafter, a process of generating plasma in a space between the first shower head 300 and the second shower head 400 and between the first body 410 and the second body 420 of the second shower head 400 will be described in detail.

When a raw material gas is supplied over the first shower head 300 from the first gas supply line 510, the raw material gas may be sprayed to the lower side of the first shower head 300 through the plurality of holes 300a. In this case, when RF power is supplied to the first body 410 of the second shower head 400 by the first power supply unit 460 and the first shower head 300 is grounded, a first plasma may be generated due to a discharge of the raw material gas in a space between the first shower head 300 and the first body 410. Hereinafter, the space between first shower head 300 and the second shower head 400, preferably, between the first shower head 300 and the first body 410 will be referred to as a ‘first plasma region P1’, and the plasma generated in the first plasma region P1 will be referred to as the first plasma. Since the first plasma region P1 is defined by a structure in which the upper part (i.e., first shower head 300) is grounded and RF power is applied to the lower part (i.e., first body 410), the first plasma generated in the first plasma region P1 may be high in density and ion energy. Here, the first plasma may be a Reactive Ion Deposition (RID) type of plasma that is generated when the upper part is grounded and the lower part is applied with RF power, may be high in density and ion energy and wide in sheath region. The first plasma generated in the first plasma region P1 may move to the lower side of the second shower head 400 through the connection tube 430. Hereinafter, the lower side of the second shower head 400, i.e., a region between the second body 420 and the substrate support 210 will be referred to as a ‘reaction region R’. Here, the first plasma has the characteristics of high density and high ion energy.

Also, when a raw material gas is supplied from the second gas supply line 520 into the second shower head 400, i.e., a gap between the first body 410 and the second body 420, the raw material gas may be diffused into the space between the first body 410 and the second body 420. In this case, when RF power is supplied to the first body 410 of the second shower head 400 by the first power supply unit 460 and the second body 420 is grounded, a second plasma may be generated in the space between the first body 410 and the second body 420. Here, the second plasma may be a Plasma Enhanced CVD (PE-CVD) type of plasma that is generated when RF power is applied to the upper part thereof and the lower part thereof is grounded, and may low in plasma density and wide in sheath region. Also, the process speed may be high.

Hereinafter, the space between the first body 410 and the second body 420 of the second shower head 400 will be referred to as a ‘second plasma region P2’, and the plasma generated in the second plasma region P2 will be referred to as the second plasma. Since the second plasma region P2 is defined by a structure in which the lower part (i.e., second body 420) is grounded and RF power is applied to the upper part (i.e., first body 410), the second plasma generated in the second plasma region P2 may be relatively low in density and ion energy compared to the first plasma. Thereafter, the second plasma generated in the second plasma region P2 may move to the reaction region R through the plurality of first spray holes 440a prepared in the second body 420.

Thus, as the raw material gas is sprayed through the first shower head 300 and the second shower head 400, respectively, the raw material gas can be sprayed in time-sharing manner. Also, since the application of power to the first shower head 300 and the application of power to the second shower head 400 are independently controlled, the plasma generated in the first plasma region P1 between the first shower head 300 and the second shower head 400 and the second plasma region P2 inside the second shower head 400 can be independently controlled. Accordingly, a film with good step coverage can be achieved.

In this case, since a bias power is applied to the substrate support 210 on which the substrate S is seated through the second power supply unit 230, ions of the first and second plasmas moving to the reaction region R may be incident to or collide with the surface of the substrate S, thereby etching a thin film disposed on the substrate S or depositing a thin film on the substrate S. As described above, the first plasma generated in the first plasma region P1 has the characteristics of high density and high ion energy, and the second plasma generated in the second plasma region P2 may be low in density and ion energy compared to the first plasma. Thus, when only the first plasma is used like a related-art, the substrate S or a thin film formed on the substrate S may be damaged. On the other hand, when only the second plasma is used, the process speed may be slow. However, like the embodiment, when the first plasma with high density and ion energy and the second plasma with low density and ion energy compared to the first plasma are together generated, a damage of the substrate S or a thin film can be prevented by an interaction of the first plasma and the second plasma, and the process speed can be improved.

As shown in FIG. 1, it has been described that the first shower head 300 is disposed under the first insulating member 110a while being spaced therefrom and the plurality of holes 300a are prepared in the first shower head 300. However, without being limited thereto, like a second embodiment as shown in FIG. 2, the first shower head 300 may be disposed under so as to contact the lower part of the first insulating member 110a, and a plurality of holes 300a may not be prepared. In this case, the first gas supply line 510 may spray a raw material gas to the lower side of the first shower head 300.

Also, as shown in FIGS. 1 and 2, the first body 410 of the second shower head 400 may be connected to the first power supply unit 460, and RF power may be supplied to the first body 410 and the first shower head 300 and the second body 420 are grounded. However, without being limited thereto, like a third embodiment as shown in FIG. 3, the first body 410 of the second shower head 400 may be grounded, and a third power supply unit 310 for applying, e.g., RF power may be connected to the first shower head 300 disposed over the first body 410. Also, a fourth power supply unit 470 may be connected to the second body 420 under the first body 410. Thus, since the first plasma region P1 has a structure in which the upper part (i.e., first shower head 300) is supplied with power and the lower part (i.e., first body 410) is grounded, the first plasma generated in the first plasma region P1 may be lower in density and ion energy than the second plasma. Also, since the second plasma region P2 has a structure in which the upper part (first body) is grounded and the lower part (second body 420) is supplied with power, the second plasma generated in the second plasma region P2 is higher in density and ion energy than the first plasma generated in the first plasma region P1. In this case, as shown in FIG. 3, a cooling unit 300b may be inserted into the first shower head 300 to cool the first shower head 300.

Hereinafter, an operation of the substrate processing apparatus and a substrate processing method in accordance with the first embodiment will be described with reference to FIG. 1.

First, a substrate S may be loaded into the chamber 100, and may be seated on the substrate support 210. The substrate S may be a wafer, but without being limited thereto, may include a glass substrate, a polymer substrate, a plastic substrate, a metallic substrate, and other various kinds of substrate S.

When the substrate S is seated on the substrate support 310, a raw material gas may be supplied to the upper side of the first shower head 300 through the first gas supply line 510, and a raw material gas may be supplied between the first body 410 and the second body 420 of the second shower head 400 through the second gas supply line 520. The raw material gas may include one of SiH4, TEOS, O2, Ar, He, NH3, N2O, N2, and CaHb, but without being limited thereto, may include various kinds of raw material gas. In this embodiment, an etching gas for etching a thin film disposed on a substrate may be used as a raw material gas.

RF power is supplied to the first body 410 of the second shower head 400 by the first power supply unit 460, and the first shower head 300 and the second body 420 of the second shower head 400 may be grounded, respectively. Thus, the raw material gas supplied from the first gas supply line 510 may be sprayed to the lower side of the first shower head 300, i.e., the first plasma region P1 through the plurality of holes 300a prepared in the first shower head 300. Thereafter, the first plasma with high density and ion energy may be generated in the first plasma region P1 by the first shower head 300 grounded and the first body 410 supplied with RF power. The first plasma generated in the first plasma region P1 may move to reaction region R through the connection tube 430. Here, since the connection tube 430, as described above, extends from the inside of the first body 410 to the inside of the second body 420 disposed under the first body 410, the first plasma generated in the first plasma region P1 may be uniformly sprayed to the reaction region R through the connection tube 430, making the density of the first plasma uniform in the reaction region R.

Also, the raw material gas provided from the second gas supply line 520 may be uniformly diffused in a region between the first body 410 and the second body 420 of the second shower head 400, i.e., over the whole of the second plasma region P2. Thereafter, the second plasma may be generated in the second plasma region P2 by the first body 410 supplied with RF power and the second body 420 grounded. The second plasma generated in the second plasma region P2 may move to the reaction region R through the plurality of first spray holes 440a, and may be uniformly diffused over the whole of the reaction region R through the plurality of first spray holes 440a.

The first and second plasmas that move to the reaction region R may vary in characteristics such as density and ion energy due to an interaction between the first and second plasmas. That is, the first plasma moving to the reaction region R may decreases in density and ion energy compared to when the first plasma is in the first plasma region P1, which is caused by an offset effect due to the second plasma met in the reaction region R. Also, the second plasma moving to the reaction region R may increase in density and ion energy compared to when the second plasma is in the second plasma region P2, which is caused by the first plasma met in the reaction region R.

Thereafter, the first and second plasma ions of the reaction region R may be incident to or collide with the substrate S supplied with bias power, thereby etching a thin film formed on the substrate S. Although not shown, a mask (not shown) provided with a plurality of openings may be disposed over the substrate S, ions of the first and second plasmas may be incident to the substrate S through the plurality of openings of the mask (not shown), etching the thin film formed on the substrate S. In this embodiment, since plasma with high density and ion energy and plasma with low density and ion energy are together used instead of using only one of plasma with high density and ion energy and plasma with low density and ion energy like in a related art, the thin film or the substrate S can be prevented from being damaged by ions directing to the substrate S, and the process time can be shortened.

So far, the substrate processing apparatus in accordance with the first embodiment of FIG. 1 has been exemplified, but the operation and the plasma generation process of the substrate processing apparatus in accordance with the second embodiment of FIG. 2 and the substrate processing apparatus in accordance with the third embodiment of FIG. 3 are similar to those of the first embodiment. However, in the second embodiment of FIG. 2, a raw material gas supplied from the first gas supply line 230 may be sprayed to the lower side of the first shower head 300. Also, in the third embodiment of FIG. 3, the first shower head 300 and the second body 420 of the second shower head 400 may be grounded, and the first body 410 of the second shower head 400 may be connected to the power supply unit 470. Thus, the first plasma may be generated between the first shower head 300 and the first body 410, and the second plasma may be generated between the first body 410 and the second body 420. In this case, the second plasma may be relatively high in density and high ion energy compared to the first plasma. Thus, the second plasma generated between the first body 410 and the second body 420 may be relatively high in density and ion energy compared to the first plasma generated between the first shower head 300 and the first body 410.

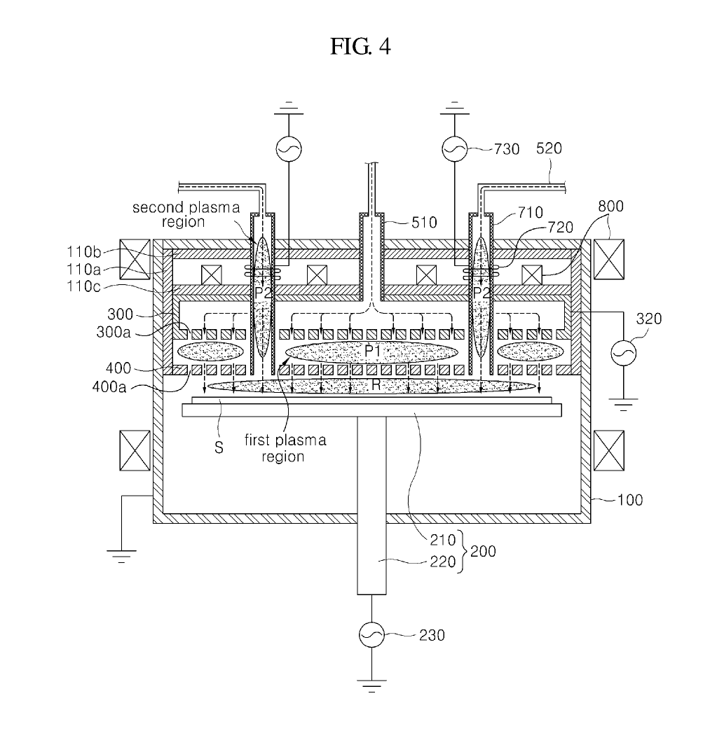

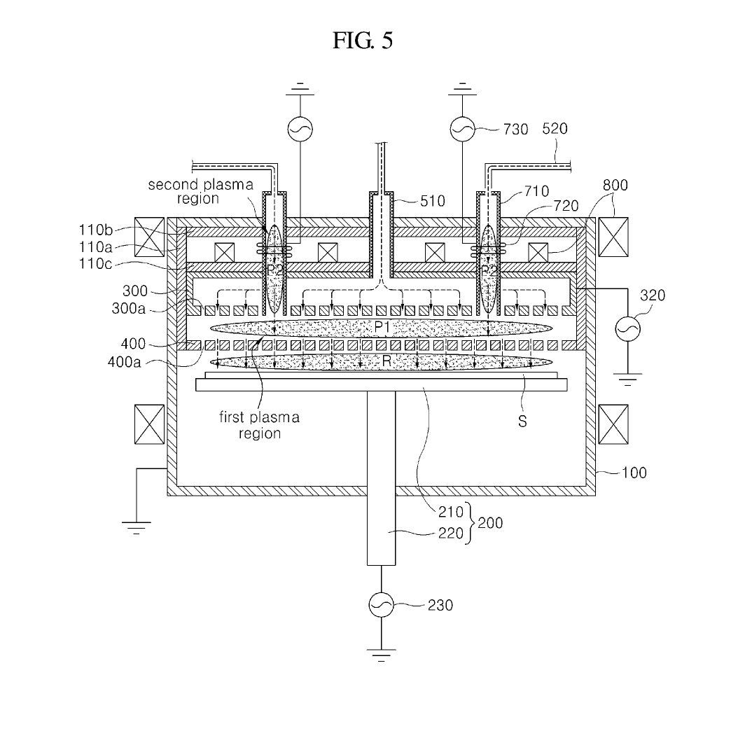

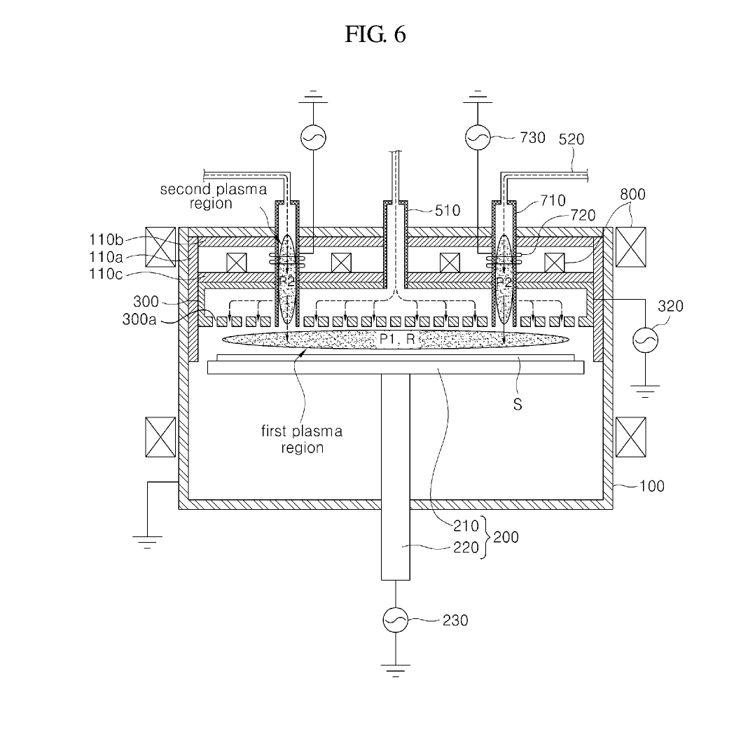

FIG. 4 is a cross-sectional view illustrating a substrate processing apparatus in accordance with a fourth embodiment, and FIGS. 5 and 6 are cross-sectional views illustrating substrate processing apparatuses in accordance with fifth and sixth embodiments.

Referring to FIG. 4, the substrate processing apparatus in accordance with the fourth embodiment may include a chamber 100 having an internal space for processing a substrate S, a substrate supporting unit 200 disposed inside the chamber 100 to fixedly support the substrate S thereon, first and second shower heads 300 and 400 disposed over the substrate supporting unit 200 inside the chamber 100 to spray a raw material gas and vertically spaced from each other, a plasma generation tube 710 penetrating through the first and second shower heads 300 and 400 disposed in a vertical direction and generating plasma therein, an antenna 720 wound around an outer circumferential surface of the plasma generation tube 710, and a plurality of magnetic field generation units 800 disposed on at least one of the inside and the outside of the chamber 100. Also, the substrate processing apparatus may further include a first raw material supply line 510 having one end thereof connected to the first shower head 300 to supply a raw material gas to the first shower head 300, a second raw material supply line 520 having one end thereof connected to the plasma generation tube 710 to supply a raw material gas to the plasma generation tube 720, a first power supply unit 330 for applying power to the first shower head 300, a second power supply unit 730 for applying power to the antenna 720, and a third power supply unit 230 for supplying bias power to the substrate support unit 200. Here, the raw material gases supplied to the first shower head 300 and the plasma generation tube 710 may be the same or different from each other in accordance with the type of films formed on the substrate S and the type of etching. For example, in order to form an oxide (SiO2) film on the substrate S, an O2 or N2O gas may be supplied to the first shower head 300 to form plasma, and an SiH4 or TEOS gas may be injected into the plasma generation tube 710 to form plasma. In case of etching, XF series (NF3, F2, C3F8, and SF6) and O2 may be supplied to the first shower head 300 and the plasma generation tube 710. Also, inert gases such as He, Ar, and N2 may be supplied to the first shower head 300 and the plasma generation tube 710. Examples of etching gas may include NF3, F2, BC13, CH4, C12, CF4, CHF3, CH2F2, C2F6, C3F8, C4F8, C5F8, and C4F6. Without being limited thereto, the thin film may be formed using SiH4, TEOS, O2, NH4, N2O, and CaHb (hydrocarbon compound), and inert gases such as He, Ar, and N2 may be used as an auxiliary gas for the transfer of the raw material and the generation of plasma.

The chamber 100 may be manufactured in a hollow hexahedral shape, but may have a certain internal space therein. This chamber 100 may be grounded. In this embodiment, since the first and second shower heads 300 and 400, the plasma generation tube 710, and the plurality of magnetic generation unit 800 are disposed at the upper side of the chamber 100, it is necessary to insulate among the first and second shower heads 300 and 400, the plasma generation tube 710, and the plurality of magnetic generation unit 800. Accordingly, a first insulating member 110 may be mounted on the inner side wall of the chamber 100 where the first and second shower heads 300 and 400, the plasma generation tube 710, and the plurality of magnetic generation unit 800 are disposed, and a second insulating member 110b may be mounted on the upper wall of the chamber 100. Also, a third insulating member 110c may be mounted on the upper surface of the first shower head 300.

The substrate supporting unit 200 may be disposed under the second shower head 400 in the chamber 100, and may include a substrate support 210 on which the substrate S is seated and a shaft 220 having one end thereof connected to the substrate support 210 and the other end thereof protruding from the lower part of the chamber 100 to be connected to the third power supply unit 230.

The first shower head 300 may extend in a width direction of the chamber 100 over the substrate support unit 200, and may spray a raw material gas through the plurality of first spray holes 300a. Also, the first shower head 300 may be connected to the first raw material supply line 510 for supplying a raw material gas and the first power supply unit 320 that applies power for generating plasma. The second shower head 400 may be located between the first shower head 300 and the substrate support 210 in the chamber 100, and may be disposed along the extending direction of the first shower head 300 to be grounded. Also, a plurality of second spray holes 400a may be prepared in the second shower head 400. The second spray hole 400 may be located directly under the first spray hole 300a prepared in the first shower head 300. The first spray hole 300a and the second spray hole 400a may communicated with each other such that the raw material gas passing through the first spray hole 300a can be introduced into the second spray hole 400a. Without being limited thereto, the first spray hole 300a and the second spray hole 400a may also be disposed to alternate with each other. Here, the size of the first spray hole 300a and the second spray hole 400a may be equal to or greater than about 0.01 inch, respectively. This is for preventing arcking upon application of power to the first shower head 300 from occurring in the first shower head 300 and the second shower head 400 and suppressing the generation of parasitic plasma.

Hereinafter, a process of generating plasma in a space between the first shower head 300 and the second shower head 400 will be described.

When a raw material gas is supplied from the first gas supply line 510 to the first shower head 300, the raw material gas may be sprayed to the space between the first shower head 300 and the second shower head 400 through the plurality of first holes 300a. In this case, when the first power supply unit 320 supplies RF power to the first shower head 300 and the second shower head 400 is grounded, a plasma, preferably, Capacitive Coupled Plasma (CCP) may be generated due to a discharge of the raw material gas in the space between the first shower head 300 and the second shower head 400. Hereinafter, the space between the first shower head 300 and the second shower head 400 will be referred to as a ‘first plasma region P1’. A plasma gas generated in the first plasma region P1 may move to the lower side of the second shower head 400 through the plurality of second spray holes 400a of the second shower head 400. In this case, since a bias power is applied to the substrate support 210 on which the substrate S is seated, cations of the plasma within a range between the second shower head 400 and the substrate S may be incident to or collide with the surface of the substrate S, thereby etching the substrate S or a thin film disposed on the substrate S. Here, since a certain low DC power is applied to the substrate support 210, a separate plasma due to the second shower head 400 and the substrate support 210 may not be generated. Hereinafter, the region between the second shower head 400 and the substrate S will be referred to as a ‘reaction region R’. Thus, CCP generated in the first plasma region P1 may compensate for the reduction of the density while resonance plasma generated from the plasma generation tube 710 described later reaches the substrate S. That is, the resonance plasma generated in the plasma generation tube 710 tends to decrease in density as becoming distant from the antenna 720. Accordingly, the resonance plasma generated from the plasma generation tube 710 may decrease in density while reaching the substrate S. Thus, in this embodiment, the CCP may be additionally generated to compensate for the physical density reduction of the resonance plasma. Also, the resonance plasma generated in the plasma generation tube 710 may be high in ion energy and movement speed. Accordingly, when only the resonance plasma is used, the substrate S or a thin film formed on the substrate S may be damaged. However, like the embodiment, when the CCP with low density and ion energy compared to the resonance plasma are together generated in the plasma region P1, a damage of the substrate S or a thin film can be prevented by an interaction of the resonance plasma and the CCP.

The plasma generation tube 710 may be manufactured in a pipe shape having an internal space, and the antenna 720 may be wounded around the outer circumferential surface thereof. The plasma generation tube 710 may extend in a longitudinal direction of the chamber 100, and may penetrate the first and second shower heads 300 and 400 in a vertical direction. That is, the plasma generation tube 710 may extend from the upper side of the first shower head 300 to the lower part of the second shower head 400, and the lower part of the plasma generation tube 710 may not protrude from the lower part of the second shower head 400. In this embodiment, the plasma generation tube 710 may be prepared in plurality, and may be disposed spaced from each other. The plasma generation tube 710 may be manufactured using an insulating material such as Pyrex and ceramic. For example, the plasma generation tube 710 may be manufactured into an insulating container using Pyrex and ceramic. The antenna 720 may be wound around the outer circumferential surface of the plasma generation tube 710, i.e., insulating container, and one end thereof may be connected to the second power supply unit 730. The antenna 720 in accordance with the embodiment may be formed of copper (Cu), and may be helically wound around the outer circumferential surface of the plasma generation tube 710. However, the shape of the antenna 720 is not limited to the helical shape described above, but may include various types such as Nagoya type, half-Nagoya type, double-leg type, double half-turn type, Boswell (double saddle) type, Shoji type, and phased type. The antenna 720 may have a length of an integer multiple of 212 when the excitation frequency wavelength is λ. The is for reducing the generation of unstable plasma upon application of RF power, by winding the antenna 720 around the plurality of plasma generation tubes 710, respectively, and thus quickly matching the impedances of the plurality of antennas 720.

Hereinafter, a process of generating plasma inside the plasma generation tube 710 will be described.

When a raw material gas may be supplied from the second raw material supply line 520 to the plasma generation tube 710 and RF power is applied to the antenna 720 by the second power supply unit, a plasma may be generated in the plasma generation tube 710 due to a discharge of the raw material gas. Hereinafter, the inside of the plasma generation tube 710 will be referred to as a ‘second plasma region P2’. In this case, since the antenna 720 is helically wound around the plasma generation tube 710, and the length of the antenna 720 is an integer multiple of 212, and the reaction is performed in a narrow space inside the plasma generation tube 710, a resonance plasma with high density may be generated in the second plasma region P2. Cations of the resonance plasma generated in the second plasma region P2 may be incident to or collide with the surface of the substrate S seated on the substrate support 210 due to a bias power applied to the substrate support 210. Thus, a thin film can be formed on the substrate S, or the substrate S or the thin film formed on the substrate S can be etched.

Thus, the resonance plasma generated in the second plasma region P2 may have the characteristics of high density, and may have an effect of improving the process speed because the ion energy and plasma density toward the substrate S are high. However, the density may be reduced while the resonance plasma reaches the substrate S. In this case, CCP generated in the first plasma region P1 may compensate for the reduction of the density. Accordingly, the total density of plasma reacting with the substrate S can be prevented from being reduced. Also, the resonance plasma generated in the plasma generation tube 710 may be high in ion energy and movement speed. Accordingly, when only the resonance plasma is used, the substrate S or a thin film formed on the substrate S may be damaged. However, like the embodiment, when the CCP with low density and ion energy compared to the resonance plasma are together generated in the plasma region P1, a damage of the substrate S or a thin film can be prevented by an interaction of the resonance plasma and the CCP.

A magnetic field generation unit 800 may be disposed inside and outside the chamber 100 to serve to generate a magnetic field such that the plasmas generated in the first and second plasma regions P1 and P2 can be uniformly diffused. The magnetic field generation unit 800 may be disposed on at least one of the inside and the outside of the chamber 100. The magnetic field generation unit 800 disposed inside the chamber 100 may be located over the third insulating member 110c mounted on the first shower head 300. That is, the magnetic field generation unit 800 disposed inside the chamber 100 may mounted between the second insulating member 110b mounted on the upper wall inside the chamber 100 and the third insulating member 110c mounted on the upper part of the first shower head 300. Also, the magnetic field generation units 800 may be disposed spaced from each other between the plurality of plasma generation tubes 710. The magnetic field generation unit 800 disposed outside the chamber 100 may surround the chamber 100, and may be disposed at the upper side and the lower side of the chamber 100. The magnetic field generation unit 800 disposed outside the chamber 100 may vary in location. The magnetic field generation unit 800 may be formed of an electromagnet coil. Here, the magnetic field generation unit 800 may be manufactured into a coil type. The magnetic field generation unit 800 disposed inside the chamber 100 may surround the plasma generation tube 710, and the magnetic field generation unit 800 disposed outside the chamber 100 may surround the chamber 100. When power is applied to the magnetic field generation unit 800, a magnetic field may be generated outside and inside the chamber 100. The magnetic field may allow the plasmas generated in the first and second plasma regions P1 and P2 to be uniformly diffused. For example, when the magnetic field generation unit 800 is not mounted, the plasma density may be high inside the second plasma generation tube 710, but may be low in the reaction region R corresponding to the lower side of the second shower head 400. Accordingly, the magnetic field generation unit 800 may be mounted outside and inside the chamber 100 to form a magnetic field, thereby inducing the resonance plasma to perform a linear motion in accordance with the magnetic flux of the magnetic field. Thus, the resonance plasma inside the plasma generation tube 710 may move to the outside to be uniformly diffused over the whole of the reaction region R.

It has been described that the plasma generation tube 710 extends from the upper side of the first shower head 300 to the lower part of the second shower head 400. However, without being limited thereto, like a fifth embodiment of FIG. 5, the plasma generation tube 710 may extend from the upper side of the first shower head 300 to the lower part of the first shower head 300. That is, the plasma generation tube 710 may be disposed so as not to protrude from the lower part of the first shower head 300. Also, like a sixth embodiment of FIG. 6, while the second shower head 400 is not installed under the first shower head 300, the plasma generation tube 710 may extend from the upper side of the first shower head 300 to the lower part of the first shower head 300.

Also, it has been described in FIGS. 4 to 6 that the magnetic field generation unit 800 is disposed on both the inside and the outside of the chamber 100. However, without being limited thereto, in the fourth to sixth embodiments of FIGS. 4 to 6, the magnetic field generation unit 800 may also be disposed on one of the inside and the outside of the chamber 100.

Hereinafter, an operation of the substrate processing apparatus and a substrate processing method in accordance with the fourth embodiment will be described with reference to FIG. 4.

First, a substrate S may be loaded into the chamber 100, and may be seated on the substrate support 210 disposed in the chamber 100. When the substrate S is seated on the substrate support 310, a raw material gas may be supplied to the first shower head 300 through the first gas supply line 510, and RF power may be applied to the first shower head 300 using the first power supply unit 320. In this case, the second shower head 400 may be grounded. Also, bias power may be applied to the substrate support 210, and power may be applied to the plurality of magnetic field generation unit 800 disposed inside and outside the chamber to generate a magnetic field. Thus, the raw material gas may be sprayed to the space, i.e., the first plasma region P1 between the first shower head 300 and the second shower head 400 through the plurality of first holes 300a of the first shower head 300. Since RF power is applied to the first shower head 300 and the second shower head 400 is grounded, CCCP may be generated in the first plasma region P1. Thereafter, the CCP generated in the first plasma region P1 may move to the lower side of the second shower head 400, i.e., reaction region R through the plurality of second spray holes 400a of the second shower head 400.

A raw material gas may be supplied to the first shower head 300 through the first raw material supply line 510, and RF power may be applied to the first shower head 300. In this case, a raw material gas may be supplied into the plasma generation tube 710 through the second raw material supply line 520, and RF power may be applied to the antenna 720 wound around the plasma generation tube 710 using the second power supply unit 730. Thus, a resonance plasma may be generated in the inside of the plasma generation tube 710, i.e., the second plasma region P2. In this case, the resonance plasma generated in the inside of the plasma generation tube 710, i.e., the second plasma region P2 may move to the reaction region R while performing a linear motion by the magnetic flux of the magnetic field generated by the magnetic field generation unit 800. Accordingly, the resonance plasma generated in the second plasma region P2 may be uniformly diffused over the whole of the reaction region R.

Thus, the plasmas generated in the first and second plasma regions P1 and P2 may form a thin film on the substrate S, or may etch the substrate S or the thin film. That is, cations of the plasmas generated in the first and second plasma regions P1 and P2 may be incident to or collide with the substrate S supplied with bias power, thereby forming a thin film on the substrate S or etching the substrate S or the thin film.

Meanwhile, the density of the resonance plasma generated in the second plasma region P2 may be reduced while the resonance plasma is moving the substrate S. In this case, CCP generated in the first plasma region P1 may compensate for the reduction of the density. Accordingly, the reduction of the process speed due to the reduction of the density of the resonance plasma can be prevented, and the substrate processing time can be shortened compared to a related art. Also, the resonance plasma generated in the plasma generation tube 710 may be high in ion energy and plasma density. Accordingly, when only the resonance plasma is used, the substrate S or a thin film formed on the substrate S may be damaged. However, like the embodiment, when the CCP with low density and ion energy compared to the resonance plasma are together generated in the plasma region P1, a damage of the substrate S or a thin film can be prevented by an interaction of the resonance plasma and the CCP. Accordingly, a thin film with a good film quality can be formed.

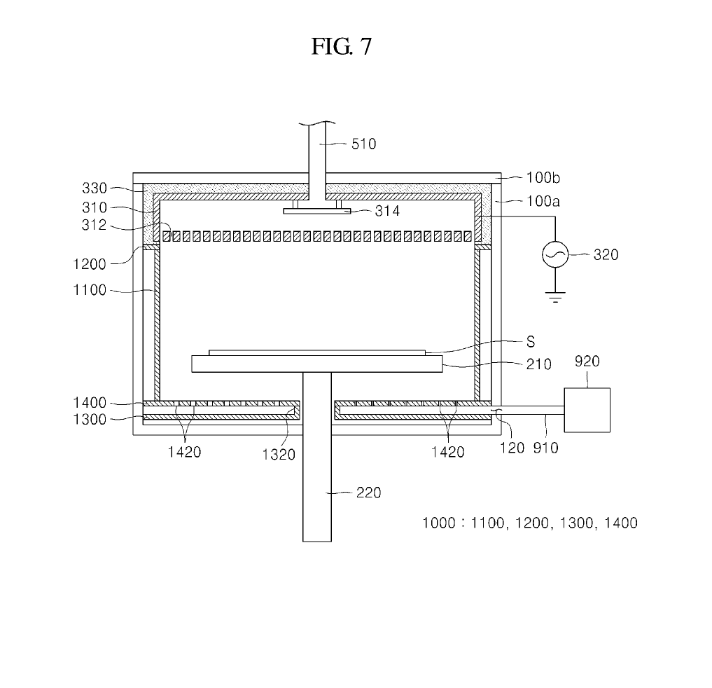

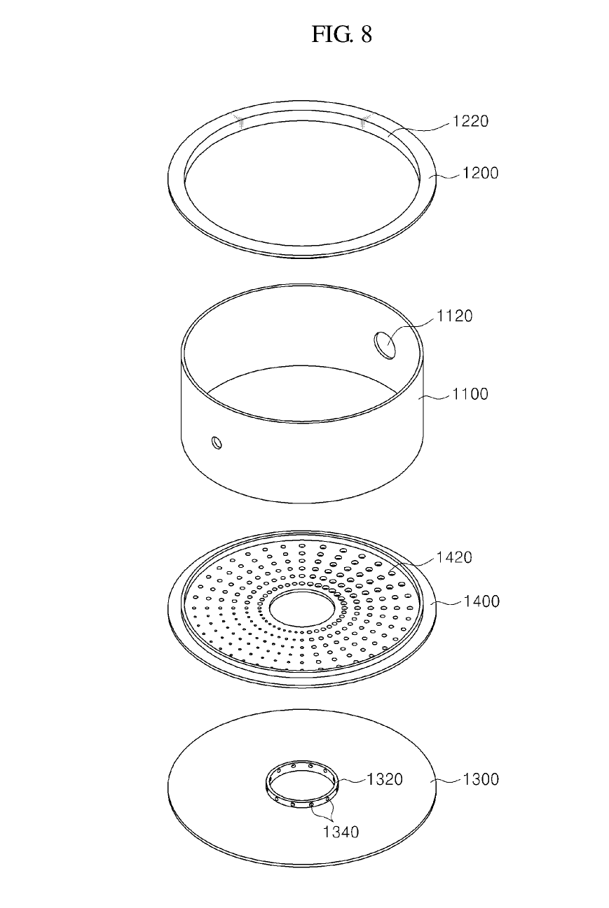

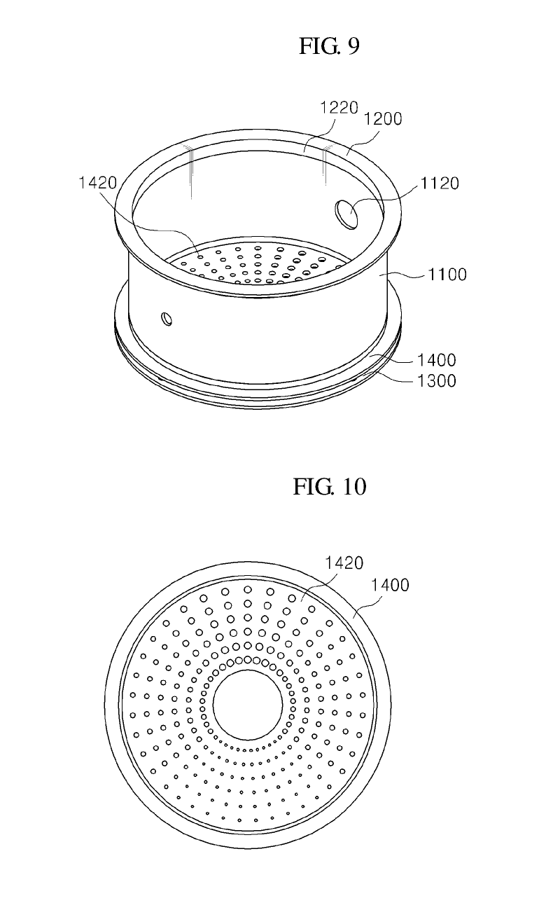

FIG. 7 is a cross-sectional view illustrating a substrate processing apparatus in accordance with a seventh embodiment. Also, FIG. 8 is an exploded perspective view illustrating a liner assembly used in substrate processing apparatuses in accordance with embodiments. FIG. 9 is an assembly perspective view, and FIG. 10 is a plan view of an intermediate liner.

Referring to FIG. 7, a substrate processing apparatus in accordance with a seventh embodiment may include a chamber 100 prepared with a certain reaction space, a substrate support unit 200 disposed at the lower part of the chamber 100 to support a substrate S, a shower head 310 for spraying a process gas into the chamber 100, a gas supply line 510 for supplying a process gas, a discharge unit 900 disposed outside the chamber 100 to discharge the inside of the chamber 100, and a liner assembly 1000 prepared inside the chamber 100 to protect the inner side wall of the chamber 100 and allow the gas flow in the chamber 100 to be uniform.

The chamber 100 may include a certain reaction region, and may be maintained airtight. The chamber 100 may include a reaction part 100a including a substantially circular planar portion and a side wall portion that upwardly extends from the planar portion, and a cover 100b disposed on the reaction part 100a to airtightly seal the chamber 100 and having a substantially circular shape. A discharge port 120 may be formed in the side surface of the chamber 100, e.g., under the substrate support 210, and the discharge port 120 may be connected to the discharge unit 900 including a discharge line and a discharge apparatus.

The substrate support unit 200 may be prepared inside the chamber 100, and may be disposed at a location opposite to the shower head 300. That is, the shower head 300 may be prepared at the upper side of the inside of the chamber 100, and the substrate support unit 200 may be prepared at the lower side of the inside of the chamber 100.

The shower head 310 may spray a process gas such as deposition gas and etching gas into the chamber 100, and the power supply unit 320 may applies a high frequency power to the shower head 310. The shower head 310 may be disposed at a location of the upper part of the chamber 100 opposite to the substrate support 210, and may spray a process gas to a lower side of the chamber 100. The shower head 310 may have a certain space therein. The shower head 310 may be connected to a process gas supply line 510 at the upper side thereof, and a plurality of spray holes 312 for spraying the process gas to the substrate S may be formed at the lower side of the shower head 310. Also, the shower head 310 may be further provided with a distribution plate 314 for uniformly distributing the process gas supplied from the gas supply line 510. The distribution plate 314 may be connected to the process gas supply line 510 closely to a gas inflow part to which the process gas is introduced, and may have a certain plate shape. That is, the distribution plate 314 may be spaced from the upper side surface of the shower head 310 by a certain gap. Also, the distribution plate 314 may be provided with a plurality of through holes therein. Due to the distribution plate 314, the process gas supplied from the process gas supply line 510 can be uniformly distributed in the shower head 310, and thus can be uniformly sprayed to the lower side through the spray hole 312 of the shower head 310. Also, the shower head 310 may be manufactured using a conductive material such as aluminum, and may be spaced from the side wall and the cover 100b of the chamber 100 by a certain gap. An insulator 330 may be prepared between the shower head 310 and the side wall 100a and the cover 100b of the chamber 100 to insulate the shower head 310 and the chamber 100. Since the shower head 310 is manufactured with a conductive material, the shower head 310 may be supplied with high frequency power from the power supply unit 320 to be used as an upper electrode of the plasma generation unit. The power supply unit 320 may be connected to the shower head 310 through the side wall of the chamber 100 and the insulator 340, and may supply high frequency power for generating plasma to the shower head 310. The power supply unit 320 may include a high frequency power supply (not shown) and a matcher (not shown). For example, the high frequency power supply may generate high frequency power of about 13.56 MHz, and the matcher may detect the impedance of the chamber 100 to generate the imaginary number component of the impedance that is opposite in phase to the imaginary number component of the impedance, thereby supplying the maximum power into the chamber 100 such that the impedance is the same as the pure resistance that is the real number component and thus generating an optimal plasma. On the other hand, since high frequency power is applied to the shower head 310, the chamber 100 may be grounded, generating a plasma of the process gas in the chamber 100.

The process gas supply line 510 may supply a plurality of process gases, for example, an etching gas and a thin film deposition gas. The etching gas may include NH3 and NF3, and the thin film deposition gas may include SiH4 and PH3. Also, inert gases such as H2 and Ar may be supplied in addition to the etching gas and the thin film deposition gas. Also, a valve and a mass flow controller for controlling the supply of the process gas may be prepared between the process gas supply source and the process gas supply pipe.

The discharge unit 900 may be connected to the discharge port 120 formed at a lower portion of the side surface of the chamber 100. The discharge unit 900 may include a discharge pipe 910 connected to the discharge port 120, and a discharge device 920 for discharging the inside of the chamber 100 through the discharge pipe 910. In this case, the discharge device 920 may include a vacuum pump such as a turbo molecular pump, and thus may be configured to vacuum-suction the inside of the chamber 100 up to a certain pressure of about 0.1 mTorr or less, i.e., a certain decompression atmosphere. Meanwhile, the discharge unit 900 may also be prepared at the lower part of the chamber 100 that is penetrated by a shaft 220. Since the discharge unit 900 is prepared at the lower side of the chamber 100, a portion of the process gas may also be discharged through the lower side of the chamber 100.

The liner assembly 1000, as shown in FIGS. 8 to 10, may include a side liner 1100 having a substantially cylindrical shape, a upper liner 1200 prepared at the upper side of the side liner 1100, a lower liner 1300 prepared at the lower side of the side liner 1100, and an intermediate liner 1400 prepared between the lower liner 1200 and the upper liner 1300.

The side liner 1100 may be manufactured into a substantially cylindrical shape having upper and lower portions opened. The side liner 1100 may be mounted in the reaction chamber of the substrate processing apparatus to protect the inner side surface of the reaction chamber from the process gas or the plasma. The side liner 1100 may be manufactured to have the same diameter from the upper portion to the lower portion thereof. The side liner 1100 may be manufactured to have a smaller diameter as it gets closer to the lower portion thereof, that is, the side liner 1100 may downwardly incline toward the inside. When the side liner 1100 is manufactured to downwardly incline toward the inside, the flow of the reactant gas or plasma may be guided to the surrounding of the substrate support prepared at the lower side of the inside of the reaction chamber, and the high-speed discharging can be achieved due to the reduction of the discharge area. In addition, when the side liner is manufactured to downwardly incline toward the inside, a contact area with the inner side surface of the reaction chamber can be reduced, and thus polymer can be prevented from being deposited on the wall surface of the side liner 110 when being heated to a high temperature by plasma. Meanwhile, the side liner 1100 may be manufactured to have an inner diameter greater than the diameter of the substrate support. That is, when the side liner 1100 has a vertical shape or even a downwardly inclined shape, the smallest inner diameter of the side liner 1100 may be greater than the diameter of the substrate support. This is because the substrate support is prepared inside the side liner 1100 and moves in a vertical direction. An insertion hole 1120 may be formed on at least one region of the side liner 1100 to receive a measurement device for measuring a pressure and the like. The insertion hole 1120 may be formed in at least two regions on the same straight line in a vertical direction. Also, the insertion hole 1100 may be formed on two region facing each other in a horizontal direction. That is, a measurement device inserted into one insertion hole 1120 may be inserted into the other insertion hole 1120. The insertion hole 1120 may have the same or different sizes. For example, the two insertion holes 1120 may be formed to have the same size in the vertical direction, and have different sizes in the horizontal direction.

The upper liner 1200 may be manufactured into a substantially ring shape, and may be coupled to the upper part of the side liner 1100. That is, the upper liner 1200 may have an opening formed at the central portion thereof and may include a circular plate with a certain width to surround the opening, which has the substantially same size as the opening of the upper portion of the side liner 1100. The upper liner 1200 may have an opening at the central portion thereof to open the central part of the reaction space in the reaction chamber, allowing the reactant gas or the plasma to be concentrated on the central part of the reaction chamber. That is, the side liner 1100 may be spaced from the inner side wall of the reaction chamber by a certain gap, and the outer surface of the upper liner 1200 may contact the inner side wall of the reaction chamber, thereby separating a space between the side liner 1100 and the inner side wall of the reaction chamber and a space inside the side liner 1100. Also, the upper liner 1200 may have a protrusion 1220 downwardly protruding from the inner undersurface with the same width as the side liner 1100. That is, the protrusion 1220 may fixedly contact the upper surface of the side liner 1100, allowing the upper liner 1200 to be fixed on the side liner 1100. Also, instead of forming the protrusion 1220, the inner undersurface of the upper liner 1200 may fixedly contact the side liner 1100. Meanwhile, when the side liner 1100 is fully adhered to the inner wall of the chamber, the upper liner 1200 may not be needed, and the side liner 1100 and the upper liner 1200 may be integrally formed.

The lower liner 1300 may be manufactured into a substantially circular plate shape having an opening at the central portion thereof, and may be fixedly coupled to the lower part of the side liner 1100. Here, the opening of the lower liner 1300 may have a smaller diameter than the opening of the upper liner 1200. That is, the opening of the upper liner 1200 may have a diameter of the same size as the inner diameter of the side liner 1100, and the opening of the lower liner 1300 may have a smaller diameter than the inner diameter of the side liner 1100. This is because the process gas sprayed from the shower head through the opening of the upper liner 1200 is allowed to be introduced into the space inside the side liner 1100 and the shaft of the substrate support is inserted through the opening of the lower liner 1300. Also, the diameter of the lower liner 1300 may be greater than that of the side liner 1100, for example, may have the same diameter as the inner diameter of the reaction chamber. That is, the side liner 1100 may be spaced from the inner side wall of the reaction chamber by a certain gap, and the lower liner 1300 may contact the inner side wall of the reaction chamber. Also, at least a portion of the lower surface of the lower liner 1300 may contact the lower surface of the reaction chamber. Also, the lower liner 1300 may have a protrusion 1320 upwardly protruding from the inner side thereof by a certain height. The protrusion 1320 may have a plurality of holes 1340 formed therein. The plurality of holes 1340 may have the same size and shape all over the regions. However, the plurality of holes 1340 may have different sizes and shapes for each region. For example, the plurality of holes 1340 may be formed in a smaller size at a region close to the discharge port formed on the side surface of the reaction chamber, and may be formed in a larger size at a region distant from the discharge port. Also, the height of the protrusion 1320 may be adjusted in accordance with a distance between the lower liner 1300 and the intermediate liner 1400, and preferably, may be the same as the discharge port.

The intermediate liner 1400 may be prepared between the upper liner 1200 and the lower liner 1300. Preferably, a gap between the lower liner 1300 and the intermediate liner 1400 may be at least the same as the size of the discharge port. The intermediate liner 1400 may have an opening at the central portion thereof, which has the same size as the opening of the lower liner 1300. This is because the shaft 220 for supporting the substrate support 210 is located through the openings of the intermediate liner 1400 and the lower liner 1300. The intermediate liner 1400 may be manufactured into a substantially circular plate shape having an opening at the central portion thereof. The opening and the circular plate of the intermediate liner 1400 may have the same size as the opening and the circular plate of the lower liner 1300. Accordingly, the outer surface of the intermediate liner 1400 may contact the inner side wall of the reaction chamber. Also, the lower surface of the side liner 1100 may contact a certain region of the upper surface of the intermediate liner 1400. The intermediate liner 1400 may have a plurality of holes 1420 formed therein. In addition to the plurality of holes 1420, a through hole may be formed in various shapes such as a slit. That is, since the process gas at the upper side of the intermediate liner 1400 needs to flow into the lower side of the intermediate liner 1400, the plurality of holes 1420 may be formed in the intermediate liner 1400. Here, the plurality of holes 1420 may have different sizes and number for each region. For example, a hole 1420 close to the discharge port connected to the discharge apparatus may be formed in smaller size and number, and a hole 1420 distant from the discharge port may be formed in larger size and number. In other words, when the size of the holes 1420 is equal all over the regions, the number of holes 1420 may differ in each region. On the other hand, when the number of the holes 1420 is equal all over the regions, the size of holes 1420 may differ in each region. That is, the discharge pressure and speed of a region close to the discharge port may be greater than those of a region distant from the discharge port, but the discharge pressure and speed may be the same all over the regions by adjusting the size and number of holes of the intermediate liner 1400.

Meanwhile, the liner assembly 1000 may be manufactured with a ceramic or a metallic material such as aluminum or stainless steel. The liner assembly 1000 is manufactured with a metallic material, a ceramic such as Y2O3 and Al2O3 may be coated.

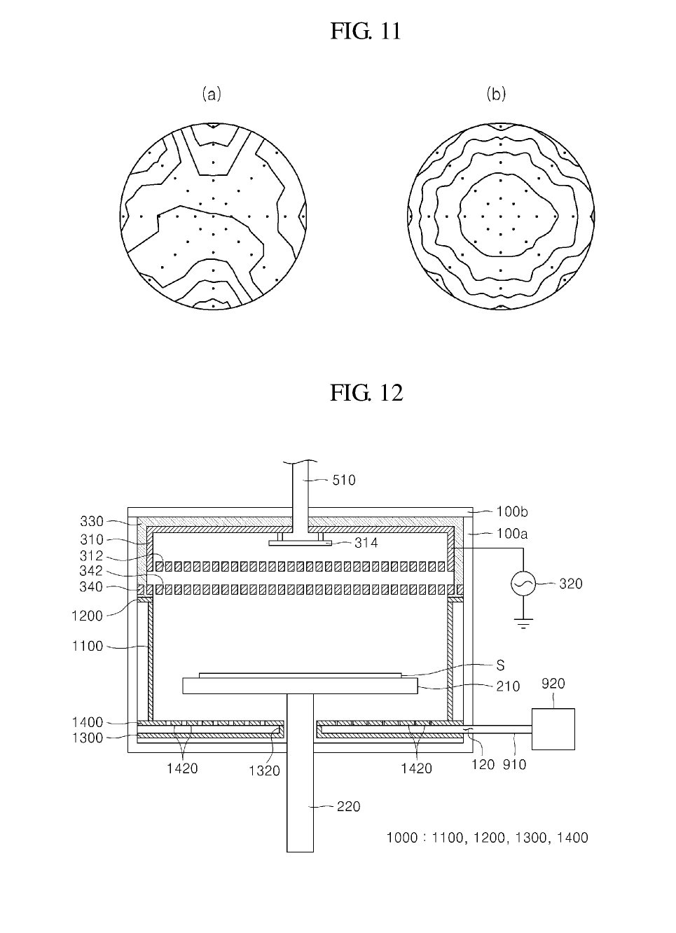

As described above, the substrate processing apparatus including the liner assembly 1000 in accordance with the embodiment may perform discharging by preparing the lower liner 1300 and the intermediate liner 1400 under the substrate support 210 and forming the discharge port 120 on the side surface of the chamber 100 therebetween. The intermediate liner 1400 may have different sizes and numbers of holes 1420. The size and number of holes 1420 may increase as getting distant from the discharge port 120, allowing a gas at the upper side of the intermediate liner 1400 to flow into the lower side of the intermediate liner 1400 through the holes 1420 of the intermediate liner 1400 and then to be discharged. Accordingly, the gas flow inside the chamber 100 can be uniformly controlled as a whole, by reducing the discharge quantity of the gas with respect to a fast gas flow of a region closer to the discharge port 120 and increasing the discharge quantity of the gas with respect to a slow gas flow of a region distant from the discharge port 120. Thus, the deposition uniformity of a thin film on the substrate S can be improved, and the generation of particles can be inhibited. That is, when comparing a related art where an intermediate liner is not used as shown in FIG. 11A with the present invention where an intermediate liner is used as shown in FIG. 11B, it can be seen that the present invention is improved in deposition uniformity compared to the related art. Since the gas flow inside the chamber 100 is uniform, a duration when the process gas stays in all regions on the substrate S may become equal to each other, thereby improving the deposition uniformity of a thin film. Also, since a duration when the process gas stays in one region does not increase, the generation of particles can be inhibited.

FIG. 12 is a cross-sectional view illustrating a substrate processing apparatus in accordance with an eighth embodiment, which includes a ground plate 340. The ground plate 340 may be spaced from the shower head 310 by a certain gap, and may be connected to the side surface of the chamber 100. The chamber 100 may be connected to a ground terminal, and thus the ground plate 340 may also maintain a ground potential. Meanwhile, a gap between the shower head 310 and the ground plate 340 may become a reaction space for exciting a process gas sprayed through the shower head 310 into a plasma state. That is, when the process gas may be sprayed through the shower head 310 and the shower head is supplied with high frequency power, the ground plate 340 may maintain the ground state, and a potential difference may occur therebetween, thereby exciting the process gas into the plasma state in the reaction space. In this case, the gap between the shower head 310 and the ground plate 340, i.e., a vertical gap of the reaction space may be maintained at the minimum gap in which plasma can be excited. For example, the gap may be maintained at a size of about 3 mm or more. The process gas excited in the reaction space needs to be sprayed onto the substrate S. For this, the ground plate 340 may be manufactured into a certain plate shape having a plurality of holes 342 that penetrate in a vertical direction. Thus, the plasma generated in the reaction space can be prevented from directly contacting the substrate S, and thus a damage of the substrate S due to the plasma can be reduced. Also, the ground plate 340 may serve to lower the electron temperature by confining plasma in the reaction space.

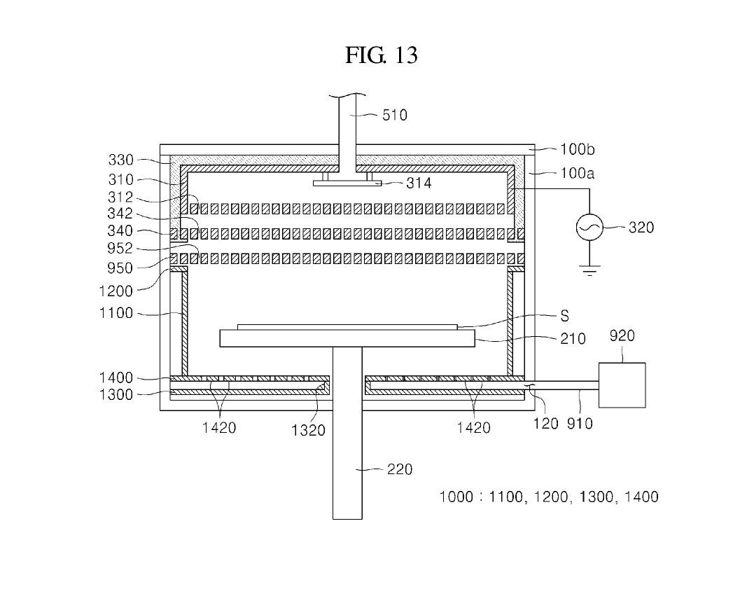

FIG. 13 is a cross-sectional view illustrating a substrate processing apparatus in accordance with a ninth embodiment, which includes a filter unit 950 between the substrate support unit 200 and the shower head 310. The filter unit 950 may be prepared between the ground plate 340 and the substrate support unit 200, and the side surface of the filter unit 950 may be connected to the side wall of the chamber 100. Accordingly, the filter unit 950 can maintain a ground potential. The filter unit 950 may filter ions, electrons, and light of plasma generated in the plasma generation unit. That is, when a plasma generated in the plasma generation unit passes through the filter, ions, electrons, and light may be blocked, allowing only reaction species to react with the substrate S. The filter unit 950 may allow plasma to collide with the filter unit 950 at least once and then to be applied to the substrate S. Thus, when the plasma collides with the filter unit 950 of the ground potential, ions and electrons with high energy may be absorbed. Also, light of the plasma may not transmit the filter unit 950 when colliding with the filter unit 950. The filter unit 950 may be prepared with various shapes. For example, the filter unit 950 may be formed using a single plate having a plurality of holes 952 formed therein, or the plate having holes formed therein may be disposed in a multi-layer and the holes 952 of each plate may be formed so as not to align with each other. Alternatively, the filter unit 950 may be formed to have a plate shape in which a plurality of holes 952 have a certain refracted path.

In accordance with an embodiment, a first plasma is generated in a first plasma region corresponding to the inside or outside of an electrode member, and a second plasma is generated in a second plasma region that is the inside of a second shower head. Here, one of the first and second plasmas is high in ion energy and density, and the other is low in ion energy and density compared thereto. Accordingly, since the first and second plasmas with different ion energies and densities are used, the substrate processing speed can be improved compared to a related art, and a damage of a substrate or a thin film can be reduced.

In accordance with another embodiment, since a resonance plasma with high ion energy and density is used, the substrate processing speed can be improved compared to a related art. Meanwhile, the density of the resonance plasma may be reduced while the resonance plasma is moving the substrate. In this case, a Capacitive Coupled Plasma (CCP) with low ion energy and plasma density compared to the resonance plasma is together formed, thereby compensating for the reduction of the density of the resonance plasma. Also, the substrate and the thin film can be prevented from being damaged, by forming both resonance plasma and CCP and controlling ion energy incident into or colliding with the substrate.

In accordance with still another embodiment, a lower liner and an intermediate liner are prepared under a substrate support and a discharge port is formed on the side surface of the reaction chamber therebetween to discharge the reaction chamber. The intermediate liner has different size or number of holes. A larger size and number of holes are formed at a region that is more distant from the discharge port. Accordingly, while the gas flow is fast at a region close to the discharge port, the discharge quantity of a gas is allowed to be reduced. On the other hand, while the gas flow is slow at a region distance from the discharge port, the discharge quantity of the gas is allowed to increase. Thus, the gas flow can be uniformed controlled in the reaction chamber as a whole. Since the gas flow can be allowed to be uniform in the reaction chamber, the deposition uniformity of a thin film on the substrate can be improved, and the generation of particles can be inhibited.

Although the liner assembly and the substrate processing apparatus including the liner assembly been described with reference to the specific embodiments, they are not limited thereto. Therefore, it will be readily understood by those skilled in the art that various modifications and changes can be made thereto without departing from the spirit and scope of the present invention defined by the appended claims.

What is claimed is:

1. A substrate processing apparatus comprising:
a chamber having a substrate processing space;
a first shower head disposed in the chamber to generate a first plasma region in the inside or outside thereof; and
a second shower head disposed at one side of the first shower head and spaced apart from the first shower head to generate a second plasma region,
wherein the second shower head comprises:
a first body disposed at one side of the first shower head and spaced apart from the first shower head;
a second body disposed under the first body and spaced apart from the first body, the second body having a plurality of first and second spray holes, which are configured to spray a gas; and
a connection tube having an inner space, the connection tube vertically passing through the first body and the second body to extend from the first body to the second body.

2. The substrate processing apparatus of claim 1, wherein the first shower head comprises a power supply unit configured to apply power to at least one of the first body and the second body.

3. The substrate processing apparatus of claim 2, wherein the power supply unit applies the power so that the first plasma region is formed between the first shower head and the first body, the second plasma region is formed between the first body and the second body, one of the first and second plasma has relatively high ion energy and density, and the other plasma has relatively low ion energy and density.

4. The substrate processing apparatus of claim 1, wherein the inside of the connection tube communicates with the first plasma region, the first spray hole defined in the second body communicates with the second plasma region, and an end of the connection tube is inserted into the second spray hole.

5. The substrate processing apparatus of claim 4, wherein the connection tube is formed of an insulation material, and a region of the connection tube, which is connected to the first body, has a diameter greater than that of a region of the connection tube, which is connected to the second body.

6. The substrate processing apparatus of claim 1, further comprising a second gas supply line having at least one end inserted into the chamber to supply a source gas into a region between the first body and the second body of the shower head.

7. The substrate processing apparatus of claim 6, wherein the at least one end of the second gas supply line is inserted into an inner wall of the chamber to face the region between the first body and the second body.

8. The substrate processing apparatus of claim 1, wherein an insulation member formed of an insulation material is disposed around the first body and the shower head on an inner wall of the chamber.

9. The substrate processing apparatus of claim 1, further comprising a liner assembly disposed in the chamber,
wherein the liner assembly comprises:
a side liner having a cylindrical shape with upper and lower sides opened;
an intermediate liner disposed under the side liner, the intermediate liner having a plurality of first holes vertically passing therethrough; and
a lower liner disposed under the intermediate liner,
wherein the plurality of first holes are defined in different sizes and numbers in a plurality of regions.

10. The substrate processing apparatus of claim 9, wherein each of the lower liner and the intermediate liner has an opening in a central portion thereof,
wherein the opening has a size less than a diameter of the side liner, and a support rod configured to support a substrate support is inserted into the opening.

11. The substrate processing apparatus of claim 10, wherein a protrusion protruding upward from the lower liner to contact the intermediate liner is further disposed inside the lower line, and
a plurality of second holes are defined in the protrusion.
